(19) United States
(12) Patent Application Publication
(10) Pub. No.: US 2019/0206882 A1
(43) Pub. Date: Jul. 4, 2019

(54) MEMORIES WITH SOURCE DIFFUSIONS ELECTRICALLY COUPLED TO SOURCE-CONTACTED LAYERS

(71) Applicant: TEXAS INSTRUMENTS INCORPORATED, Dallas, TX (US)

(72) Inventor: John Howard MacPEAK, Garland, TX (US)

(21) Appl. No.: 15/859,426

(22) Filed: Dec. 30, 2017

(51) Int. Cl. H01L 27/11521; H01L 29/08; H01L 29/423; H01L 23/528; H01L 23/522; H01L 29/06; H01L 21/265; H01L 21/768; H01L 21/3213; H01L 29/66; H01L 29/788; H01L 21/28; H01L 29/51; G11C 16/04; G11C 16/26; G11C 16/10; G11C 16/14

(52) U.S. Cl. CPC H01L 27/11521; G11C 2216/04; H01L 29/42328; H01L 23/528; H01L 23/5226; H01L 29/0649; H01L 21/26513; H01L 21/76802; H01L 21/76877; H01L 21/32133; H01L 29/66825; H01L 29/788; H01L 21/28273; H01L 29/513; G11C 16/0408; G11C 16/26; G11C 16/10; G11C 16/14; H01L 29/0847

(57) ABSTRACT

A memory comprises: a substrate; a dielectric region formed on the substrate; a source-contacted layer formed in the dielectric region; a first source diffusion formed in the substrate; a first drain diffusion formed in the substrate; a first floating gate formed in the dielectric region; a first control gate formed in the dielectric region; a first erase gate formed in the dielectric region; and a first source diffusion via electrically coupling the first source diffusion to the source-contacted layer.

### BACKGROUND

Many present-day flash memory arrays have memory cells that are erasable, so that in addition to storing data for read operations, erase operations can be performed on flash memory arrays so that old data may be overwritten with new data. An erase operation involves driving sufficient source-drain current through the memory cells. Accordingly, it may be desirable to reduce unwanted IR voltage drops and to provide sufficiently uniform source-drain current distribution throughout the memory array when performing an erase operation.

### SUMMARY

In accordance with a first set of embodiments, a memory comprises: a substrate; a dielectric region formed on the substrate; a source-contacted layer formed in the dielectric region; a first source diffusion formed in the substrate; a first drain diffusion formed in the substrate; a first floating gate formed in the dielectric region; a first control gate formed in the dielectric region; a first erase gate formed in the dielectric region; and a first source diffusion via electrically coupling the first source diffusion to the source-contacted layer.

In accordance with the first set of embodiments, the memory further comprises: a second source diffusion formed in the substrate; a second floating gate formed in the dielectric region; a second control gate formed in the dielectric region; a second erase gate formed in the dielectric region; and a second source diffusion via electrically coupling the second source diffusion to the source-contacted layer.

In accordance with the first set of embodiments, the memory further comprises a bitline electrically coupled to the first drain diffusion.

In accordance with the first set of embodiments, the memory further comprises: a drain-contacted layer formed in the dielectric region; a first drain diffusion via electrically coupling the first drain diffusion to the drain-contacted layer; and a first bitline via electrically coupling the bitline to the drain-contacted layer.

In accordance with the first set of embodiments, the memory further comprises: a second drain diffusion formed in the substrate; a third floating gate formed in the dielectric region; a third control gate formed in the dielectric region; a third erase gate formed in the dielectric region; and a bitline electrically coupled to the first and second drain diffusions.

In accordance with the first set of embodiments, the memory further comprises: a drain-contacted layer formed in the dielectric region; a first drain diffusion via electrically coupling the first drain diffusion to the drain-contacted layer; a first bitline via electrically coupling the bitline to the drain-contacted layer; and a second drain diffusion via electrically coupling the second drain diffusion to the drain-contacted layer.

In accordance with the first set of embodiments, the memory further comprises: a second drain diffusion formed in the substrate; a third floating gate formed in the dielectric region; a third control gate formed in the dielectric region; and a third erase gate formed in the dielectric region.

In accordance with the first set of embodiments, the memory further comprises a bitline electrically coupled to the first and second drain diffusions.

In accordance with the first set of embodiments, the memory further comprises: a drain-contacted layer formed in the dielectric region; a first drain diffusion via electrically coupling the first drain diffusion to the drain-contacted layer; a first bitline via electrically coupling the bitline to the drain-contacted layer; and a second drain diffusion via electrically coupling the second drain diffusion to the drain-contacted layer.

In accordance with the first set of embodiments, in the memory, the first source diffusion and first drain diffusion are n-doped regions of the substrate.

In accordance with the first set of embodiments, in the memory, the dielectric region comprises an oxide layer.

In accordance with the first set of embodiments, the memory further comprises a wordline gate formed in the dielectric region.

In accordance with a second set of embodiments, a method comprises: implanting dopants in a substrate to form source diffusions and drain diffusions in the substrate; forming erase gates, wherein corresponding to each source diffusion are two erase gates; forming vias to the source diffusions and to the drain diffusions; forming a conductive layer in contact with the vias; and etching the conductive layer to form a source-contacted layer in contact with the vias to the source diffusions, and to form a drain-contacted layer in contact with the vias to the drain diffusions.

In accordance with the second set of embodiments, the method further comprises: forming a first dielectric layer on the substrate; forming a first conductive layer on the first dielectric layer; forming a second dielectric layer over the first conductive layer; forming a second conductive layer over the second dielectric layer; etching the second and first conductive layers and the first and second dielectric layers to form control gates and floating gates; implanting dopants in the substrate to form the source diffusions in the substrate; forming a third dielectric layer over the source diffusions; depositing a third conductive layer over the third dielectric layer; and etching the third conductive layer and the third dielectric layer to form the erase gates and wordline gates.

In accordance with the second set of embodiments, the method further comprises: forming bitline vias to contact the drain-contacted layer; and forming bitlines to contact the bitline vias.

In accordance with a third set of embodiments, a memory comprises: a substrate; a row of source diffusions formed in the substrate; a first row of drain diffusions formed in the substrate in one-to-one correspondence with the row of source diffusions; a first row of erase gates in two-to-one correspondence with the row of source diffusions; a second row of drain diffusions formed in the substrate in one-to-one correspondence with the row of source diffusions; a second row of erase gates in two-to-one correspondence with the row of source diffusions; and a source-contacted layer electrically coupled to the row of source diffusions.

In accordance with the third set of embodiments, in the memory, the row of source diffusions, the first row of drain diffusions, and the second row of drain diffusions have a uniform pitch.

In accordance with the third set of embodiments, the memory further comprises a first plurality of vias electrically coupling the row of source diffusions to the source-contacted layer.

In accordance with the third set of embodiments, the memory further comprises: a drain-contacted layer; and a second plurality of vias electrically coupling the first and second rows of drain diffusions to the drain-contacted layer.

### BRIEF DESCRIPTION OF THE DRAWINGS

In the drawings:

FIG. 1 shows memory cells;

FIG. 2 shows a layout for the memory cells of FIG. 1;

FIG. 3 shows memory cells in accordance with various examples;

FIG. 4 shows memory cells in accordance with various examples;

FIG. 5 shows a layout for the memory cells of FIG. 3 and FIG. 4 in accordance with various examples; and

FIG. 6 shows a process flow in accordance with various examples.

### DETAILED DESCRIPTION

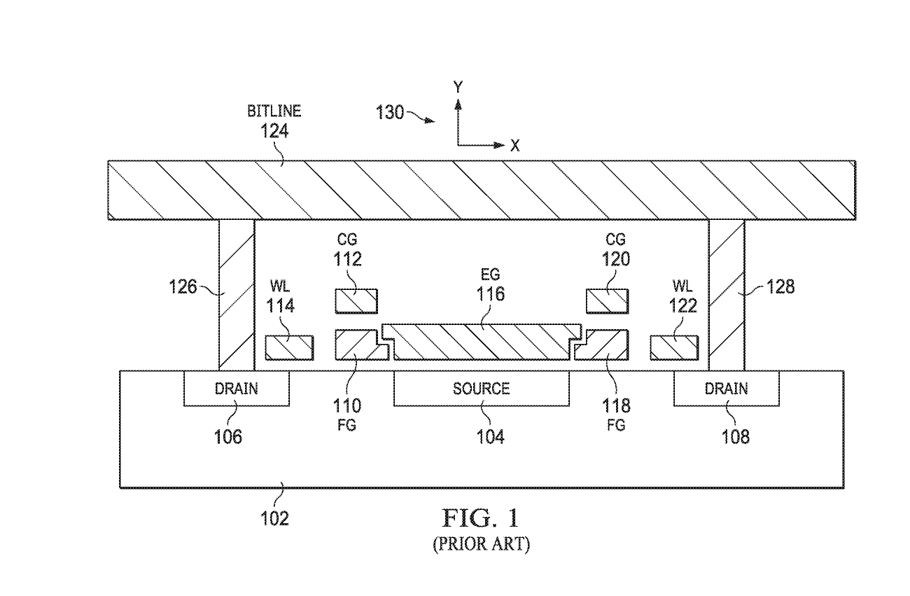

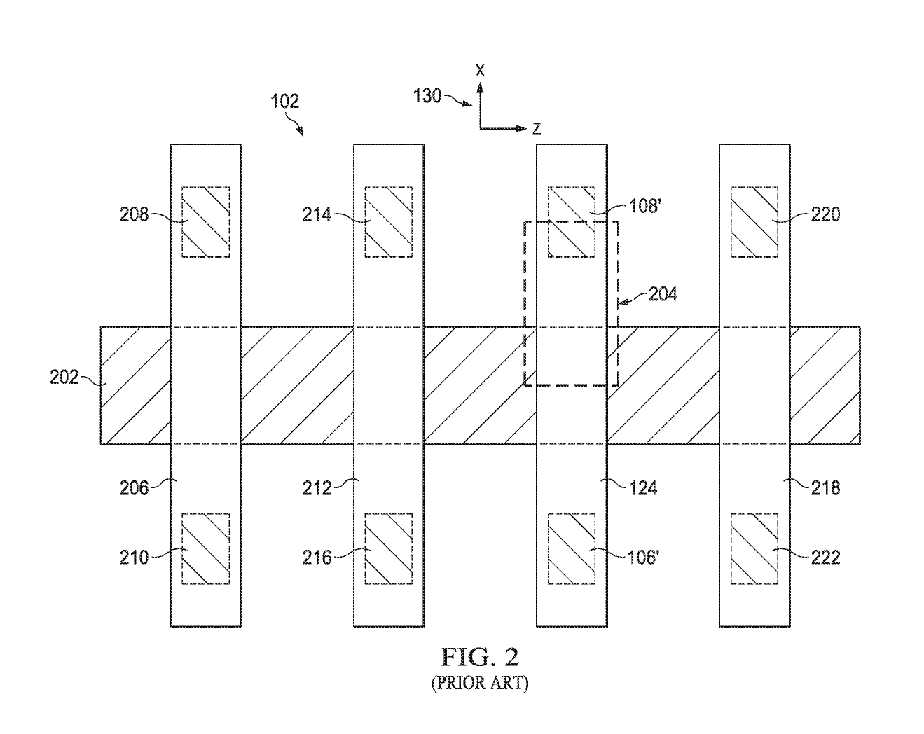

In accordance with the disclosed embodiments, a system comprises memory cells configured into a flash memory array. It is pedagogically useful to first consider conventional memory cells and memory arrays as illustrated in FIG. 1 and FIG. 2.

FIG. 1 depicts a cross section of two memory cells. The type of memory cell is a split-gate flash memory cell. Formed in a substrate 102 are a source diffusion 104, a drain diffusion 106, and a drain diffusion 108. The structure of a first memory cell includes the source diffusion 104 and the drain diffusion 106, and further includes a floating gate 110, a control gate 112, a wordline gate 114, and an erase gate 116. The structure of the second memory cell includes the source diffusion 104 and the drain diffusion 108, and further includes a floating gate 118, a control gate 120, a wordline gate 122, and the erase gate 116. The two memory cells share the source diffusion 104 and the erase gate 116.

A bitline 124 is electrically coupled to the drain diffusions 106 and 108 by way of vias 126 and 128, respectively. A coordinate system 130 has its x-axis and y-axis in the page of the drawing for FIG. 1, and is introduced to provide relative orientations among the various drawings as discussed below. As will be described later, the source diffusion 104 is electrically coupled to other memory cells (not shown in FIG. 1), and may be referred to as a common source.

For ease of illustration, FIG. 1 does not depict the complete structure that would be expected in a cross section of a memory cell. For example, it is clear from FIG. 1 that the illustrated gates would in practice be in contact with and supported by various dielectric compositions and films, such as for example SiO₂ (silicon dioxide) or ONO (oxide-nitride-oxide) film. Furthermore, various vias and electrical contacts are made to the various gates, but for ease of illustration such vias and contacts are not illustrated in FIG. 1.

As is well known, the charge stored on a floating gate determines the state of the corresponding memory cell, where the threshold voltage to turn ON the memory cell depends upon the charge stored on the floating gate, as well as other structural parameters. For example, consider the memory cell defined by the source diffusion 104, the drain diffusion 106, and the gates 110, 112, 114, and 116. During a read operation, the control gate 112 is biased at a voltage in between a low value and a high value, where the low value is the minimum value of the threshold voltage sufficient to turn ON the memory cell when the floating gate 110 does not store charge (excess electrons), and the high value is the minimum value of the threshold voltage sufficient to turn ON the memory cell when the floating gate 110 stores charge. A memory cell is turned ON when there is a source-drain current. A typical value for a bias voltage for the control gate 112 is about 1.8V.

During a read operation, the erase gate 116 is grounded (substrate voltage) or floated, and the wordline gate 114 is biased at a sufficiently high voltage (as an example, around 1.2V) so that the effective pass transistor comprising the drain diffusion 106 and the wordline gate 114 is turned ON. Biasing the wordline gate 114 selects the corresponding memory cell for a read operation. A sense amplifier (not shown) is coupled to the bitline 124 to sense a source-drain current, depending upon the state of the memory cell.

If the state of the memory cell is such that the floating gate 110 stores charge (a “0” bit is stored), then biasing the control gate 112 at the bias value is not sufficient to turn ON the memory cell, in which case a sense amplifier coupled to the bitline 124 does not sense a source-drain current. If the state of the memory cell is such that the floating gate 110 does not store charge (a “1” bit is stored), then biasing the control gate 112 at the bias value is sufficient to turn ON the memory cell, in which case a sense amplifier coupled to the bitline 124 will sense a source-drain current.

The method of source-side-injection may be used to program the memory cell. For example, to inject charge into the floating gate 110 so that the memory cell stores a “0” bit, the source diffusion 104 is biased sufficiently high (an example being between 4.5 V to 5.0V), the wordline gate 114 is biased at an intermediate value (an example being about 0.8V), the bitline 124 is brought LOW (grounded or at the substrate voltage), and the erase gate 116 is electrically coupled to the control gate 112 so that they are at the same potential.

To erase the memory cell, the erase gate 116 is biased to a sufficiently high voltage (for example, about 14V). The other gates (i.e., the gates 110, 112, and 114), the drain diffusion 106, and the source diffusion 104 are all grounded. With the erase gate 116 shared by the two memory cells depicted in FIG. 1, in practice both memory cells are erased during an erase operation.

FIG. 2 depicts a layout for several memory cells, including the two memory cells of FIG. 1. The depiction of the layout illustrated in FIG. 2 does not show all structures and is not drawn to scale. The coordinate system 130 in FIG. 1 is included in FIG. 2, but where now the x-axis and the z-axis lie in the page of the drawing as shown to indicate the orientation of the depiction in FIG. 2 relative to that of FIG. 1.

A common source 202 is illustrated in FIG. 2. The common source 202 is formed in the substrate 102 and comprises a plurality of source diffusions and their electrical coupling to one another. For example, if the source diffusion of each memory cell comprises an n-doped region of the substrate 102, then a common source 202 may be formed by implanting electron donors into the substrate 102 to form an n-doped region comprising the source diffusions and their interconnections.

The bitline 124 of FIG. 1 is included in FIG. 2, but with an orientation indicated by the coordinate system 130 in FIG. 2. A dashed rectangle 204 is drawn in FIG. 2 to indicate a typical memory cell, such as for example the memory cell of FIG. 1 defined by the source diffusion 104, the drain diffusion 108, and the gates 116, 118, 120, and 122. A contact 108′ in FIG. 2 denotes an electrical coupling of the bitline 124 to the drain 108 illustrated in FIG. 1 by way of one or more vias and possibly one or more metal layers (not shown). With respect to FIG. 2, the drain diffusion 108 would lie underneath the contact 108′ but is not shown for ease of illustration.

A contact 106′ in FIG. 2 provides electrical coupling of the bitline 124 to the drain diffusion 106 illustrated in FIG. 1, where the drain diffusion 106 would lie underneath the contact 106′ but is not shown for ease of illustration.

FIG. 2 depicts a layout associated with several memory cells. A bitline 206 and contacts 208 and 210 represent a pair of memory cells sharing a source diffusion and an erase gate (not shown), where the contacts 208 and 210 provide electrical coupling of the bitline 206 to underlying drain diffusions (not shown). Similarly, a bitline 212 with contacts 214 and 216 represent a pair of memory cells sharing a source diffusion and an erase gate (not shown), and a bitline 218 with contacts 220 and 222 represent a pair of memory cells sharing a source diffusion and an erase gate (not shown).

Only four pairs of memory cells are represented in FIG. 2, but in practice many such pairs of memory cells would be fabricated on a chip to provide a memory array. The layout illustrated in FIG. 2 would be repeated along the x-axis and z-axis directions. For ease of illustration, FIG. 2 does not illustrate all structures for a typical memory array. For example, not shown are contacts and interconnects to the erase gates, control gates, and wordline gates in the memory cells of the memory array, as well as the sense amplifiers, address decoders, drivers, and other control circuits for performing operations to read, write, and erase various memory cells.

There are several problems associated with the memory array of FIG. 2 comprising the memory cells as illustrated in FIG. 1. There may be unwanted IR voltage drops along the common source 202. This may impact memory bit cells that are relatively far away from those source diffusions that are electrically coupled to ground (substrate). This may cause spreading of the source-drain current distribution when performing an erase operation. A layout that provides relatively frequent ground couplings of source diffusions may help mitigate this problem, but at the expense of additional chip area. Furthermore, sophisticated OPC (Optical Proximity Correction) mask design may be needed to pattern the common source 202 and the interconnects needed to ground the source diffusions for multiple memory cells, which may challenge STI (Shallow Trench Isolation) fill capabilities for a given process technology node.

An embodiment memory array includes memory cells where each memory cell has its own erase gate proximal to a shared source diffusion, and where metal layers are formed to electrically couple multiple source diffusions. Accordingly, diffusions in the active region of an embodiment are not needed to couple together the source diffusions, and such embodiments are expected to achieve a more uniform source-drain current without the voltage drop of a common source based on diffusion in the active region. Without requiring strap cells for electrically coupling a common source to ground, where the common source is based on diffusion in the active region, a more uniform pitch in the layout is expected. Uniformity in pitch simplifies mask manufacture and chip fabrication. Furthermore, in an embodiment where each memory cell has its own erase gate, an erase operation may be performed on individual rows of memory cells.

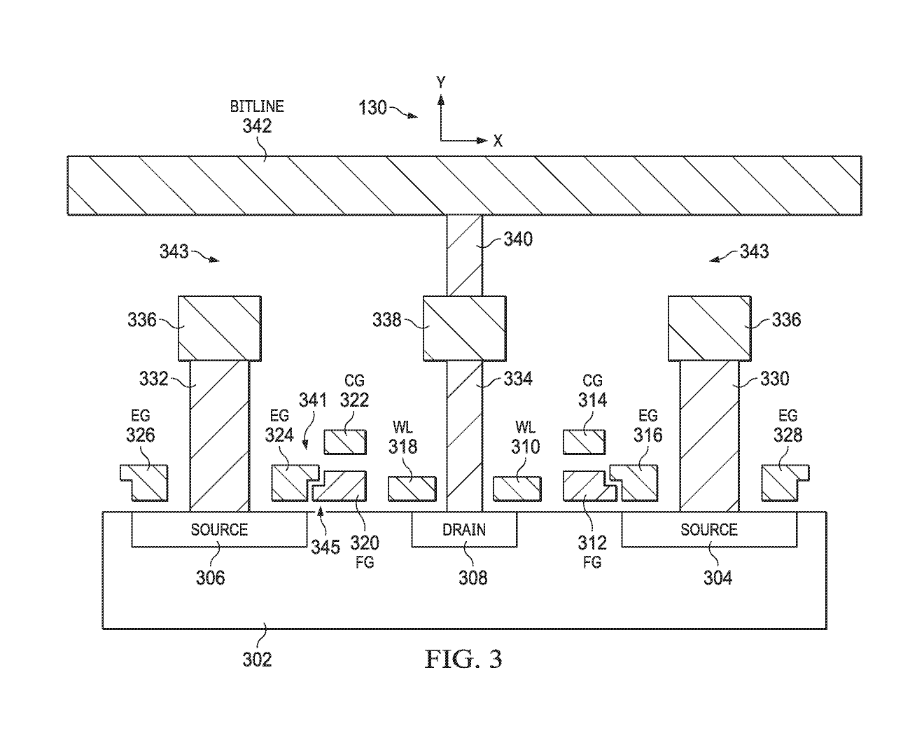

FIG. 3 depicts a cross section of two memory cells according to an illustrative embodiment. These two memory cells do not share a source diffusion, but they share a common drain diffusion. The coordinate system 130 is illustrated in FIG. 3, where the x-axis and y-axis each lie in the page of the drawing.

Formed in a substrate 302 are a first source diffusion 304, a second source diffusion 306, and a first drain diffusion 308. The first source diffusion 304, the first drain diffusion 308, a wordline gate 310, a first floating gate 312, a first control gate 314, and a first erase gate 316 together form part of a first memory cell. The functions of the wordline gate 310, the first floating gate 312, the first control gate 314, and the first erase gate 316 are similar to that of their corresponding counterparts in the memory cell illustrated in FIG. 1, so that a detailed description is not necessary to describe write, read, and erase operations, or the functions of the gates in the embodiment of FIG. 3. Similarly, the second source diffusion 306, the first drain diffusion 308, a wordline gate 318, a second floating gate 320, a second control gate 322, and a second erase gate 324 together form part of a second memory cell. A third erase gate 326 and an erase gate 328 are part of other memory cells not explicitly shown in FIG. 3 for ease of illustration. A first source diffusion via 330 and a second source diffusion via 332 are formed to provide electrical contact to the first source diffusion 304 and the second source diffusion 306, respectively. A first drain diffusion via 334 is formed to provide electrical contact to the first drain diffusion 308.

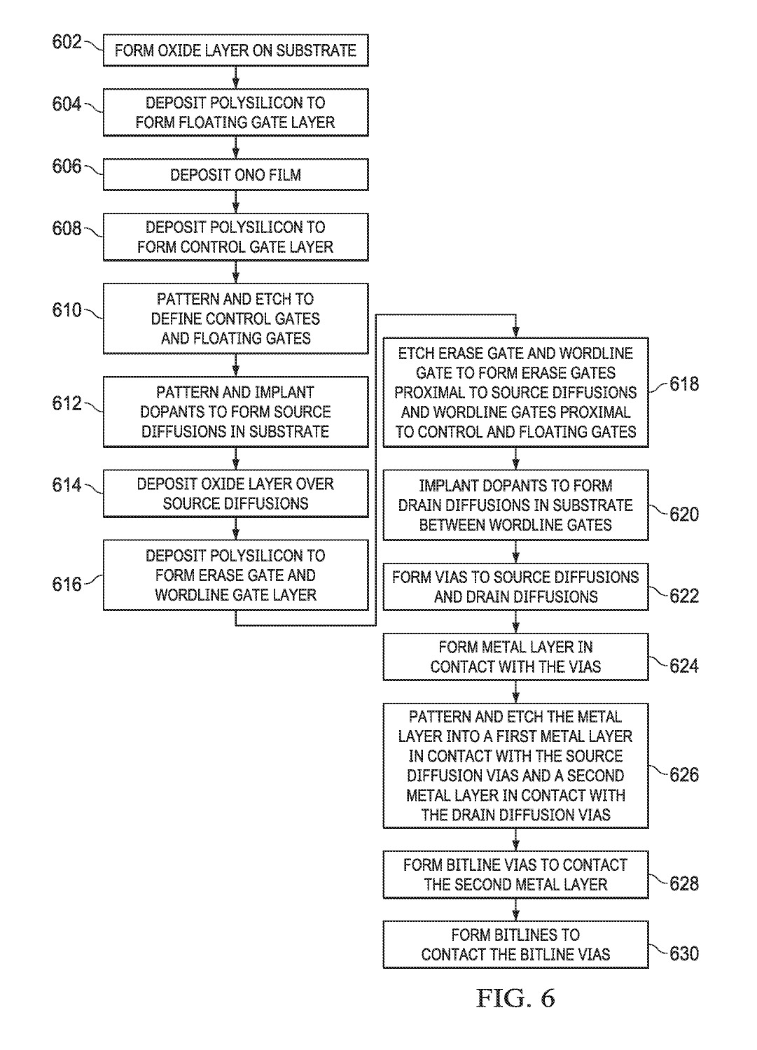

As discussed with respect to FIG. 1, various dielectric layers and films are not explicitly illustrated in FIG. 3, but such dielectrics may be part of the memory cells. For ease of illustration, a dielectric region labeled 343 is included in FIG. 3 to indicate that various dielectric layers and films are present. The dielectric region 343 is formed on the substrate 302, over multiple steps, such that various gates (to be described) are formed within the dielectric region 343. These dielectric layers are discussed in more detail with respect to the process flow of FIG. 6.

A metal layer is formed above these vias and patterned to provide interconnections. The patterning defines a source-contacted layer 336 to provide an electrical interconnect among the first source diffusion 304 and the second source diffusion 306 by way of the first source diffusion via 330 and the second source diffusion via 332, respectively. The patterning also defines a drain-contacted layer 338 to provide an electrical coupling to the first drain diffusion 308 by way of the first drain diffusion via 334. A first bitline via 340 is formed to provide electrical coupling to the drain-contacted layer 338 and a bitline 342. In this way, the bitline 342 is electrically coupled to the first drain diffusion 308.

In the particular embodiment of FIG. 3, the erase gates and floating gates have ledge extensions to help lower the voltage needed for erasing a memory cell. For example, an arrow 341 points to a ledge extension for the second erase gate 324, and an arrow 345 points to a ledge extension for the second floating gate 320. However, embodiments are not limited to erase gates and floating gates with such ledge extensions. Furthermore, other embodiments may not employ all the types of gates illustrated in FIG. 3. As an example, a memory cell in other technologies may not employ a wordline gate, where selection of memory cells is based on switching circuits coupled to source diffusions.

The relationships among the various gates and diffusions illustrated in FIG. 3 may be described by referring to an erase gate as being proximal to its corresponding source diffusion, and by referring to a wordline gate as being proximal to its corresponding drain diffusion or proximal to its corresponding floating gate and control gate. For example, the first erase gate 316 is proximal to the first source diffusion 304, and the wordline gate 310 is proximal to the first drain diffusion 308 or proximal to the first floating gate 312 and the first control gate 314. The source diffusions and the drain diffusions may be formed by implanting electron donors in the substrate 302 so that the memory cells include n-type transistors.

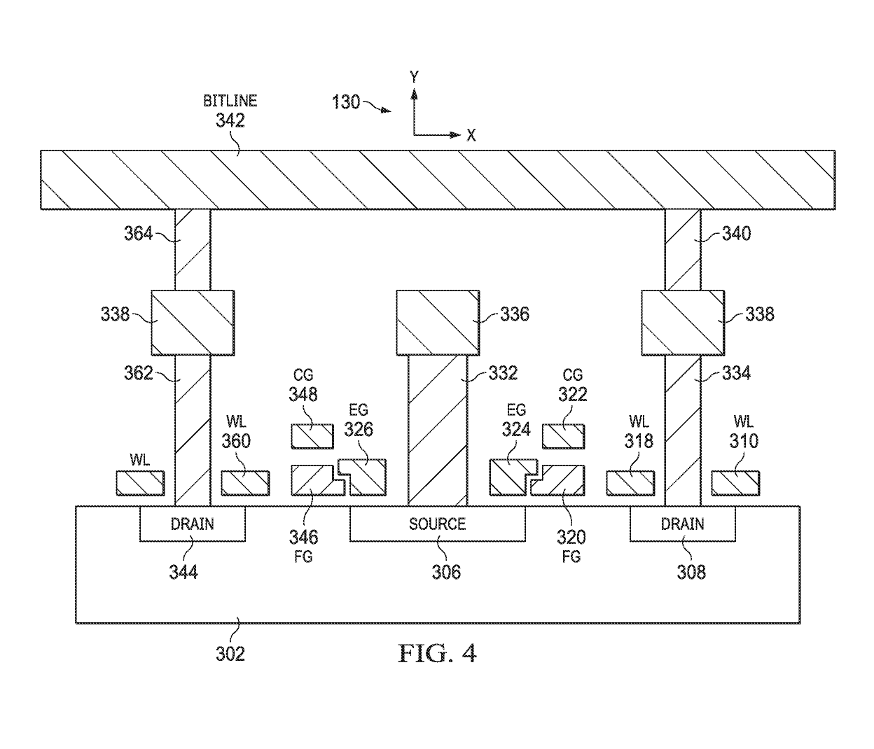

FIG. 4 depicts a cross section of two memory cells according to an illustrative embodiment, including some of the structure in FIG. 3. Specifically, the first drain diffusion 308, the second source diffusion 306, the wordline gate 310, the wordline gate 318, the second floating gate 320, the second control gate 322, the second erase gate 324, and the third erase gate 326 in FIG. 3 are illustrated in FIG. 4. FIG. 4 also illustrates the second source diffusion via 332, the first drain diffusion via 334, the first bitline via 340, the source-contacted layer 336, the drain-contacted layer 338, and the bitline 342 of FIG. 3. In addition to this shared structure, FIG. 4 depicts a second drain diffusion 344, a third floating gate 346, a third control gate 348, and a wordline gate 360. A second drain diffusion via 362 electrically couples the drain-contacted layer 338 to the second drain diffusion 344, and a second bitline via 364 electrically couples the bitline 342 to the drain-contacted layer 338 so that the bitline 342 is electrically coupled to the second drain diffusion 344. (The second bitline via 364 may be redundant because of the first bitline via 340.)

In FIG. 4, the memory cell defined by the second source diffusion 306, the first drain diffusion 308, the wordline gate 318, the second floating gate 320, the second control gate 322, and the second erase gate 324, is the same memory cell in FIG. 3 defined by the same-labeled components. In FIG. 4, the memory cell defined by the second source diffusion 306, the second drain diffusion 344, the third erase gate 326, the third floating gate 346, the third control gate 348, and the wordline gate 360, is partially illustrated in FIG. 3 where the second source diffusion 306 and the third erase gate 326 are shown. The cross section depicted in FIG. 4 may be considered a shifted view of the cross section depicted in FIG. 3, where the shift is along the x-axis direction of the coordinate system 130, and where each drawing shows at most two memory cells with a complete memory cell in common among the two drawings.

Referring to FIG. 3 and FIG. 4, in a memory array the source-contacted layer 336 electrically couples source diffusions of contiguously arrayed memory cells. The electrical coupling of source diffusions may be considered as defining a source line corresponding to a row of memory cells. There are multiple source lines and rows in a memory array. The drain-contacted layer 338 electrically couples drain diffusions of contiguously arrayed memory cells, but this electrical coupling may be considered as defining columns of memory cells, where the bitlines run are along the columns of the memory cells in the memory array.

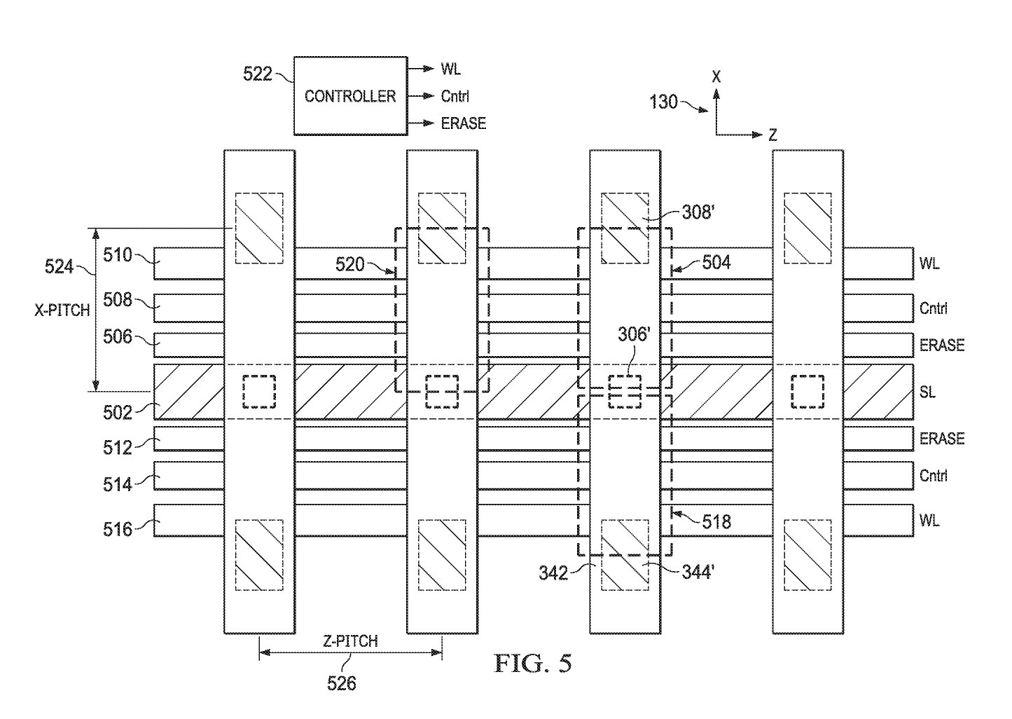

FIG. 5 depicts a layout for an illustrative memory array, including several memory cells, where the coordinate system 130 in FIG. 5 indicates the orientation of the layout in FIG. 5 with respect to the memory cells of FIG. 3 and FIG. 4. For clarity of illustration, the layout illustrated in FIG. 5 is not drawn to scale. In comparing the layout of FIG. 5 to the memory cells of FIG. 3 and FIG. 4, a metal layer 502 can be identified with the source-contacted layer 336. The metal layer 502 is referred to as a source line 502.

A dashed rectangle 504 in FIG. 5 can be identified with the memory cell of FIG. 4 defined by the second source diffusion 306, the first drain diffusion 308, the wordline gate 318, the second floating gate 320, the second control gate 322, and the second erase gate 324. A contact 306′ in FIG. 5 denotes the electrical coupling of the source line 502 to the second source diffusion 306 of FIG. 3 and FIG. 4. The bitline 342 in FIG. 3 and FIG. 4 is illustrated in FIG. 5 with the same label, but according to the orientation indicated by the coordinate system 130 in FIG. 5. A contact 308′ in FIG. 5 denotes the electrical coupling of the bitline 342 to the first drain diffusion 308 of FIG. 3 and FIG. 4.

A metal layer 506 provides electrical coupling to the erase gates in a row of memory cells, and may be referred to as an erase line 506. The erase line 506 can be identified as being electrically coupled to the second erase gate 324 of FIG. 3 and FIG. 4. A metal layer 508 provides electrical coupling to the control gates in a row of memory cells, and may be referred to as a control line 508. The control line 508 can be identified as being electrically coupled to the third control gate 322 of FIG. 3 and FIG. 4. A metal layer 510 provides electrical coupling to the wordline gates in a row of memory cells, and the metal layer 510 is referred to as a wordline 510. As an example, the wordline 510 is electrically coupled to the wordline gate 318 of FIG. 3 and FIG. 4.

A contact 344′ denotes the electrical coupling of the bitline 342 to the second drain diffusion 344 of FIG. 4. An erase line 512 provides electrical coupling to the third erase gate 326 of FIG. 4, a control line 514 provides electrical coupling to the third control gate 348 of FIG. 4, and a wordline 516 provides electrical coupling to the wordline gate 360 of FIG. 4.

A dashed rectangle 518 in FIG. 5 can be identified with the memory cell of FIG. 4 defined by the second source diffusion 306, the second drain diffusion 344, the third erase gate 326, the third floating gate 346, the third control gate 348, and the wordline gate 360. The dashed rectangle 518 is slightly displaced from the dashed rectangle 504 for clarity. The memory cells represented by the dashed rectangles 504 and 518 are contiguous memory cells belonging to a column of memory cells. By contiguous, it is meant that the two memory cells are adjacent to each other without another memory cell disposed in between.

For ease of illustration, FIG. 5 shows only two memory cells in a column, although in practice there may be a large number of such memory cells in any one column. Memory cells within the same column share a bitline, so that the bitlines in a memory array may be considered as defining the columns. Any two contiguous memory cells in a column share either a source diffusion or a drain diffusion.

A dashed rectangle 520 represents a memory cell of the same type discussed with respect to FIG. 3 and FIG. 4, where its source diffusion is electrically coupled to the source line 502. For ease of discussion, the dashed rectangle 520 will also be referred to as the memory cell 520, it being understood that the dashed rectangle 520 represents the relative position of its underlying memory cell with respect to the layout illustrated in FIG. 5. Similar remarks apply to the other dashed rectangles illustrated in FIG. 5.

The memory cells 504 and 520 are considered to belong to a row of memory cells. Each memory cell in this row shares the erase line 506, the control line 508, and the wordline 510, and each memory cell in this row has its respective source diffusions electrically coupled to the source line 502. The memory cells 504 and 520 are contiguous memory cells in the sense that there is no memory cell disposed between them.

In the same way that the bitlines of the layout illustrated in FIG. 5 may be viewed as defining the columns of a memory array, the wordlines may be viewed as defining the rows of the memory array. For ease of illustration, FIG. 5 illustrates only four columns, although in practice there are many columns in a memory array.

A controller 522 provides signals, labeled WL, Cntrl, and Erase in FIG. 5, to the various wordlines, control lines, and erase lines to perform read operations, write operations, and erase operations, as discussed with respect to the memory cells of FIG. 1. The controller 522 includes logic, timing, and drive circuits to drive various memory cell gates, depending upon a memory address, to a sufficient voltage to perform read, write, or erase operations. For example, during a read operation, the controller 522 biases selected control gates and wordlines with the WL and Control signals, depending upon the read address, to read selected memory cells, where the Erase signal grounds the erase gates of the selected memory cells.

Each memory cell in a memory array according to an embodiment includes a unique erase gate, where an erase gate is unique in the sense that it is not shared by two or more memory cells. For a memory array according to an embodiment, there is a one-to-one correspondence between a plurality of erase gates and the plurality of memory cells making up the memory array. However, two memory cells share the same source diffusion, so that there are two erase gates for each source diffusion. That is, the plurality of erase gates is in a two-to-one correspondence with a plurality of source diffusions. Because of the one-to-one correspondence of erase gates to memory cells where each memory cell has its own erase gate, the controller 522 can control each erase line individually to erase only one row of memory cells at a time. Note that there is also a one-to-one correspondence between a plurality of drain diffusions and a plurality of source diffusions in the memory array, because each memory cell includes one source diffusion and one drain diffusion.

With a metal layer (e.g., the source line 502) electrically coupling together the source diffusions in a row of memory cells, the IR voltage drops of conventional split-gate flash memory arrays are mitigated without requiring a substantial number of strap cells to connect the source diffusions to ground (or substrate). The use of a metal layer to electrically couple the source diffusions also improves source-drain current uniformity.

Furthermore, there can be more uniformity in pitch of the memory array layout when compared to designs that rely on many strap cells to connect the source diffusions to ground. Referring to FIG. 5, for the memory cells there is a uniform pitch in the column (x-axis) direction, denoted by “x-pitch” and labeled 524, and a uniform pitch in the row (z-axis) direction, denoted by “z-pitch” and labeled 526. The uniformity in column and row pitch improves manufacturability.

Electrically coupling the source diffusions by way of a metal layer, and utilizing a separate erase gate for each memory cell, may lead to slightly larger pitch for the memory cells when compared to the configuration of FIG. 1 and FIG. 2. However, this tradeoff may be desirable considering that fewer strap cells may be needed, as discussed above regarding pitch uniformity and manufacturability.

Some of the process steps involved in fabricating embodiments may be described as follows. An STI provides isolation between the columns of memory cells (e.g., the memory cells in the columns of FIG. 5). A floating gate oxide layer is formed, followed by depositing polysilicon and CMP (Chemical Mechanical Polishing) to form a floating gate layer from which the floating gates are fabricated. An ONO film is deposited, followed by depositing polysilicon to form a control gate layer from which the control gates are fabricated. A hardmask is deposited over the control gate layer, and patterning and etching are performed to define the control gates. Source and drain side offset spacers are deposited, and further etching is performed to define the floating gates.

With the control and floating gates defined, patterning and implantation are performed to form the source diffusions in the substrate. An oxide layer is formed over the source diffusions. A polysilicon layer is deposited, followed by a CMP, etchback, patterning, and etching to form the erase gates and wordline gates. Spacer layers are formed on the sides of the erase gates and wordline gates.

Patterning and etching are performed to define the drain regions between the wordline gates. Dopants are implanted to form the drain diffusions, which may be LDD (Lightly-Doped-Drains). Silicide is formed on the erase gates and wordline gates. Vias are formed to make electrical contact to the source diffusions and to the drain diffusions.

A metal layer is formed over the vias, and patterned to form a first metal layer and a second metal layer. The first metal layer is in contact with the vias to the source diffusions, and the second metal layer is in contact with the vias to the drain diffusions. The first metal layer comprises the source lines, for example the source line 502 of FIG. 5. Additional vias are formed to provide contact to the second metal layer, and bitlines are formed to provide contact to these vias so that electrical coupling is provided to the drain diffusions.

FIG. 6 illustrates a summary of the above-described process steps, it being understood that some or all of the steps illustrated in FIG. 6 comprise multiple process steps to implement. In step 602, an oxide layer is formed on a substrate, and in step 604 a polysilicon layer is deposited over the oxide layer to form a floating gate layer. In step 606 an ONO film is deposited, and in step 608 a polysilicon layer is deposited over the ONO film to form a control gate layer. Patterning and etching is performed in step 610 to define the control gates and floating gates. In step 612, patterning and doping is performed to form the source diffusions in the substrate.

In step 614 an oxide layer is formed over the source diffusions, and in step 616 polysilicon is deposited to form the layer from which the erase gates and wordline gates are fabricated, referred to as an erase gate and wordline gate layer. In step 618 the erase gate and wordline gate layer are etched to define the erase gates that are proximal to the source diffusions, and to define the wordline gates that are proximal to the control gates and floating gates. In step 620, dopants are implanted in the openings between the wordline gates to form the drain diffusions in the substrate.

In step 622, vias are formed to contact the source diffusions and the drain diffusions. The vias contacting the source diffusions may be referred to as source diffusion vias, and the vias contacting the drain diffusions as drain diffusion vias. In step 624, a metal layer is formed to contact the source diffusion vias and the drain diffusion vias, and in step 626 this metal layer is patterned and etched to form a first metal layer connected to the source diffusion vias, and a second metal layer connected to the drain diffusion vias. The first metal layer may be referred to as a source-contacted layer, and the second metal layer may be referred to as a drain-contacted layer.

In step 628 vias are formed to contact the drain-contacted layer. These vias may be referred to as bitline vias. In step 630, bitlines are formed to contact the bitline vias. These bitlines are connected to the bitline vias to form the columns as discussed with respect to FIG. 5.

In the above descriptions, reference has been made to various oxide layers that are grown or deposited onto other layers or a substrate. More generally, other types of dielectric layers may be used for such oxide layers, although for convenience such layers are often referred to as simply oxide layers. The dielectric region 343 comprises several such oxide layers built up for multiple process steps, so that the various gates and metal layers are formed in the dielectric region 343. Furthermore, reference has been made to polysilicon layers or metal layers, although more generally other kinds of conductive layers may be utilized. Accordingly, a recitation directed to an oxide layer may be replaced with a recitation directed to a dielectric layer, and a recitation directed to a polysilicon layer or a metal layer may be replaced with a recitation directed to a conductive layer.

In this disclosure, the term “couple” or “couples” is intended to mean either an indirect or direct wired or wireless connection. Thus, if a first device is coupled to a second device, that connection may be through a direct connection or through an indirect connection via other devices and connections. The above discussion is meant to be illustrative of the principles and various embodiments of the present disclosure. Numerous variations and modifications will become apparent to those skilled in the art once the above disclosure is fully appreciated. It is intended that the following claims be interpreted to embrace all such variations and modifications.

What is claimed is:

1. A memory comprising:
a substrate;
a dielectric region formed on the substrate;
a source-contacted layer formed in the dielectric region;
a first source diffusion formed in the substrate;
a first drain diffusion formed in the substrate;
a first floating gate formed in the dielectric region;
a first control gate formed in the dielectric region;
a first erase gate formed in the dielectric region; and
a first source diffusion via electrically coupling the first source diffusion to the source-contacted layer.

2. The memory of claim 1, further comprising:
a second source diffusion formed in the substrate;
a second floating gate formed in the dielectric region;
a second control gate formed in the dielectric region;
a second erase gate formed in the dielectric region; and
a second source diffusion via electrically coupling the second source diffusion to the source-contacted layer.

3. The memory of claim 2, further comprising:
a bitline electrically coupled to the first drain diffusion.

4. The memory of claim 3, further comprising:
a drain-contacted layer formed in the dielectric region;
a first drain diffusion via electrically coupling the first drain diffusion to the drain-contacted layer; and
a first bitline via electrically coupling the bitline to the drain-contacted layer.

5. The memory of claim 2, further comprising:
a second drain diffusion formed in the substrate;
a third floating gate formed in the dielectric region;
a third control gate formed in the dielectric region;
a third erase gate formed in the dielectric region; and
a bitline electrically coupled to the first and second drain diffusions.

6. The memory of claim 5, further comprising:
a drain-contacted layer formed in the dielectric region;
a first drain diffusion via electrically coupling the first drain diffusion to the drain-contacted layer;
a first bitline via electrically coupling the bitline to the drain-contacted layer; and
a second drain diffusion via electrically coupling the second drain diffusion to the drain-contacted layer.

7. The memory of claim 1, further comprising:
a second drain diffusion formed in the substrate;
a third floating gate formed in the dielectric region;
a third control gate formed in the dielectric region; and
a third erase gate formed in the dielectric region.

8. The memory of claim 7, further comprising:
a bitline electrically coupled to the first and second drain diffusions.

9. The memory of claim 8, further comprising:
a drain-contacted layer formed in the dielectric region;
a first drain diffusion via electrically coupling the first drain diffusion to the drain-contacted layer;
a first bitline via electrically coupling the bitline to the drain-contacted layer; and
a second drain diffusion via electrically coupling the second drain diffusion to the drain-contacted layer.

10. The memory of claim 1, wherein the first source diffusion and first drain diffusion are n-doped regions of the substrate.

11. The memory of claim 1, wherein the dielectric region comprises an oxide layer.

12. The memory of claim 1, further comprising a wordline gate formed in the dielectric region.

13. A method comprising:
implanting dopants in a substrate to form source diffusions and drain diffusions in the substrate;
forming erase gates, wherein corresponding to each source diffusion are two erase gates;
forming vias to the source diffusions and to the drain diffusions;
forming a conductive layer in contact with the vias; and
etching the conductive layer to form a source-contacted layer in contact with the vias to the source diffusions, and to form a drain-contacted layer in contact with the vias to the drain diffusions.

14. The method of claim 13, further comprising:
forming a first dielectric layer on the substrate;
forming a first conductive layer on the first dielectric layer;
forming a second dielectric layer over the first conductive layer;
forming a second conductive layer over the second dielectric layer;
etching the second and first conductive layers and the first and second dielectric layers to form control gates and floating gates;
implanting dopants in the substrate to form the source diffusions in the substrate;
forming a third dielectric layer over the source diffusions;
depositing a third conductive layer over the third dielectric layer; and
etching the third conductive layer and the third dielectric layer to form the erase gates and wordline gates.

15. The method of claim 14, further comprising:
forming bitline vias to contact the drain-contacted layer; and
forming bitlines to contact the bitline vias.

16. The method of claim 13, further comprising:
forming bitline vias to contact the drain-contacted layer; and
forming bitlines to contact the bitline vias.

17. A memory comprising:
a substrate;
a row of source diffusions formed in the substrate;
a first row of drain diffusions formed in the substrate in one-to-one correspondence with the row of source diffusions;
a first row of erase gates in two-to-one correspondence with the row of source diffusions;
a second row of drain diffusions formed in the substrate in one-to-one correspondence with the row of source diffusions;
a second row of erase gates in two-to-one correspondence with the row of source diffusions; and
a source-contacted layer electrically coupled to the row of source diffusions.

18. The memory of claim 17, wherein the row of source diffusions, the first row of drain diffusions, and the second row of drain diffusions have a uniform pitch.

19. The memory of claim 17, further comprising a first plurality of vias electrically coupling the row of source diffusions to the source-contacted layer.

20. The memory of claim 19, further comprising:
a drain-contacted layer; and
a second plurality of vias electrically coupling the first and second rows of drain diffusions to the drain-contacted layer.
